(19) United States
(12) Patent Application Publication
(10) Pub. No.: US 2023/0371199 A1
(43) Pub. Date: Nov. 16, 2023

(54) COLD PLATE TYPE DATA CENTER DEVICE AND DATA CENTER

(71) Applicant: Hebei Qinhuai Data Co., Limited., Huailai County (CN)

(72) Inventors: Binghua ZHANG, Huailai County (CN); Mingjiang LI, Huailai County (CN)

(21) Appl. No.: 18/144,870

(22) Filed: May 9, 2023

(30) Foreign Application Priority Data
May 12, 2022 (CN) 202210520592.4

(51) Int. Cl. H05K 7/20

(52) U.S. Cl. CPC H05K 7/20254; H05K 7/20272; H05K 7/20545; H05K 7/20645

(57) ABSTRACT

The present disclosure discloses a cold plate type data center device and a data center, which may at least include a cabinet, a heat transfer component, a circulation branch, a circulation component and a detachable mechanism, where a heat dissipation element is arranged in the cabinet. One end of the heat transfer component is in contact with the heat generating spot of the heat dissipation element, and other end of the heat transfer component passes through the cabinet and is positioned in a circulation cavity in the circulation branch. The circulation branch is communicated with the circulation component, such that a refrigerant in the circulation component flows through the circulation branch. The detachable mechanism connects the circulation component to the cabinet, and hermetically connects the circulation branch to the other end of the heat transfer component.

### CROSS-REFERENCE TO RELATED APPLICATION

This application claims priority to Chinese Patent Application No. 202210520592.4, titled “COLD PLATE TYPE DATA CENTER DEVICE AND DATA CENTER” and filed to the China National Intellectual Property Administration on May 12, 2022, the entire contents of which are incorporated herein by reference.

### TECHNICAL FIELD

The present disclosure relates to the field of electronic device, and more particularly, to a cold plate type data center device and a data center.

### BACKGROUND

With an increasing power density of a single cabinet, traditional refrigeration modes are becoming more and more unsuitable, and liquid refrigeration will become a final choice for refrigeration of data centers.

At present, there are two main types of liquid refrigeration, i.e., direct contact liquid refrigeration represented by immersion liquid refrigeration, and indirect contact liquid refrigeration represented by cold plate type liquid refrigeration. The cold plate type liquid refrigeration means that one end of a hollow metal heat transfer component is tightly attached to a CPU shell of a core heat generating spot, and then other end of the metal heat transfer component is in contact with the refrigerant. When the refrigerant passes through the other end of the metal heat transfer component, it can take away heat, thus exchanging heat and cooling the heat generating spot.

However, in most cases an end of an existing cold plate in contact with a refrigerant component is integrally formed with the refrigerant component. Thus, after a long period of refrigerant circulation of the end of the cold plate in contact with the refrigerant component, a surface of the end of the cold plate in contact with the refrigerant component may produce impurity adhesion, which may have a negative impact on refrigeration effects of the cold plate and is inconvenient for subsequent maintenance and disassembly.

### SUMMARY

An objective of the present disclosure is to provide a cold plate type data center device and a data center, which is convenient for maintenance and ensures refrigeration effects.

To achieve the above objective, one aspect of the present disclosure provides a cold plate type data center device, which may at least include a cabinet, a heat transfer component, a circulation branch, a circulation component and a detachable mechanism, where a heat dissipation element is arranged in the cabinet. One end of the heat transfer component is in contact with the heat generating spot of the heat dissipation element, and other end of the heat transfer component passes through the cabinet and is positioned in a circulation cavity in the circulation branch. The circulation branch is communicated with the circulation component, such that a refrigerant in the circulation component flows through the circulation branch. The detachable mechanism connects the circulation component to the cabinet, and hermetically connects the circulation branch to the other end of the heat transfer component.

To achieve the above objective, another aspect of the present disclosure also provides a data center, which includes the cold plate type data center device.

As can be seen, according to the technical solutions provided by the present disclosure, by arranging the heat transfer component, the circulation branch, the circulation component and the detachable mechanism, the detachable mechanism connects the circulation component to the cabinet, and hermetically connects the circulation branch to the other end of the heat transfer component, such that the heat transfer component transfers heat from the heat dissipation element to a circulating refrigerant in the circulation branch for heat exchange, thus implementing heat dissipation of the heat dissipation element. Meanwhile, the detachable mechanism connects the circulation component to the cabinet, and hermetically connects the circulation branch to the other end of the heat transfer component. Therefore, when it is necessary for maintenance or repair due to poor heat dissipation caused by impurity adhesion to a contact end between the heat transfer component and the refrigerant, it is only required to disassemble the detachable mechanism, which is convenient for disassembly and operation.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a cold plate type data center device according to an embodiment provided by the present disclosure;

FIG. 2 is a schematic diagram showing a partial structure of FIG. 1;

FIG. 3 is a schematic structural diagram of a heat transfer component according to an embodiment provided by the present disclosure;

FIG. 4 is a schematic structural diagram of a circulation branch according to an embodiment provided by the present disclosure;

FIG. 5 is a half-sectional structural diagram of a connection state between the heat transfer component and the circulation branch according to an embodiment provided by the present disclosure; and

FIG. 6 is a schematic diagram showing another partial structure of FIG. 1.

Reference numerals in the drawings: cabinet 1; heat dissipation element 11; C-shaped plate 12; groove 121; heat transfer component 2; docking cover 21; heat-conducting strip 22; heat-conducting base 221; sawtooth groove 222; circulation branch 3; docking seat 31; docking opening 311; sealing component 312; communication hole 313; duct 32; circulation component 4; liquid inlet pipe 41; liquid outlet pipe 42; upper support plate 43; lower support plate 44; detachable mechanism 5; screw 51; tightening nut 52; L-shaped plate 53; and position limit region 531.

### DETAILED DESCRIPTION

Detailed description of implementations of the present disclosure will further be made below with reference to drawings to make the above objectives, technical solutions and advantages of the present disclosure more apparent. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

With large-scale deployment of emerging technologies such as 5G, cloud computing and short videos and applications thereof, user demands are exploding geometrically, and number of data centers in China has risen rapidly. According to studies, power consumption of various data centers in use in China has reached 2% of total electricity consumption in China, and will still maintain a high-speed growth of more than 30% in the next few years. Meanwhile, an integration level of core computing units is getting higher and higher, and the power consumption of a single server is increasing, reaching a density of 8 kw/Rack at present, and likely rising to a density of 30 kw/Rack in the future.

Due to many reasons such as lagging industrial development, complex refrigeration system and low operation and maintenance level, the overall power consumption of data centers in China remains high, which is in an energy-consuming operation state, resulting in a large amount of energy waste. With the increasing power density of a single cabinet, traditional refrigeration modes have become increasingly unsuitable, and liquid refrigeration will become a final choice for refrigeration of the data centers.

At present, there are two main types of liquid refrigeration, i.e., direct contact liquid refrigeration represented by immersion liquid refrigeration, and indirect contact liquid refrigeration represented by cold plate type liquid refrigeration. The cold plate type liquid refrigeration means that one end of a hollow metal heat transfer component is tightly attached to a CPU shell of a core heat generating spot, and then other end of the metal heat transfer component is in contact with the refrigerant. When the refrigerant passes through the other end of the metal heat transfer component, it can take away heat, thus exchanging heat and cooling the heat generating spot.

However, in most cases an end of an existing cold plate in contact with a refrigerant component is integrally formed with the refrigerant component. Thus, after a long period of refrigerant circulation of the end of the cold plate in contact with the refrigerant component, a surface of the end of the cold plate in contact with the refrigerant component may produce impurity adhesion, which may have a negative impact on refrigeration effects of the cold plate and is inconvenient for subsequent maintenance and disassembly.

In an existing embodiment, in most cases the end of the cold plate in contact with the refrigerant component (i.e., the heat-conducting strip and the circulation component in the present disclosure) is integrally formed with the refrigerant component, thus it is inconvenient to maintain and repair the cold plate and the refrigerant component. Therefore, a cold plate type data center device and a data center are urgently needed, which is convenient for maintenance and ensures the refrigeration effects.

The technical solutions in the embodiment of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

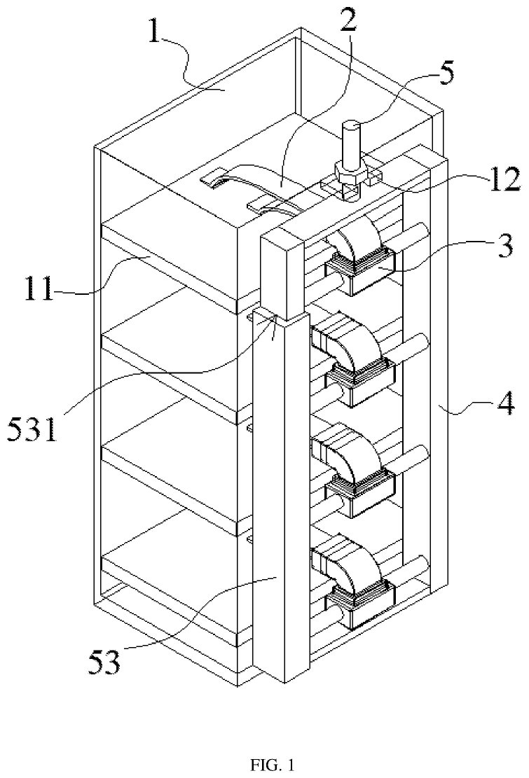

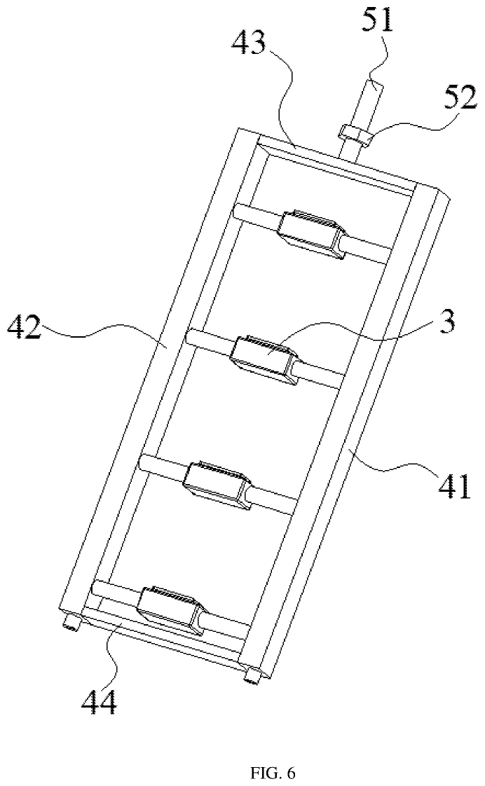

In an implementable embodiment, referring to FIG. 1 and FIG. 6, a cold plate type data center device may include a cabinet 1, a heat transfer component 2, a circulation branch 3, a circulation component 4 and a detachable mechanism 5, where a heat dissipation element 11 is arranged in the cabinet 1. The cabinet 1 is configured to support and connect the heat transfer component 2, the circulation branch 3, the circulation component 4, and the detachable mechanism 5. One end of the heat transfer component 2 is in contact with the heat generating spot of the heat dissipation element 11, and other end of the heat transfer component 2 passes through the cabinet 1 and is positioned in a circulation cavity in the circulation branch 3. Thus, when the heat generating spot of the heat dissipation element 11 generates heat, the heat transfer component 2 may transfer the heat generated by the heat dissipation element 11 to the refrigerant in the circulation cavity in the circulation branch 3, such that the heat may be carried away by the refrigerant to achieve heat exchange. The circulation branch 3 is communicated with the circulation component 4, such that the refrigerant in the circulation component 4 flows through the circulation branch 3. The detachable mechanism 5 connects the circulation component 4 to the cabinet 1, and hermetically connects the circulation branch 3 to the other end of the heat transfer component 2.

In practical application, the heat generating spot of the heat dissipation element 11 may be a server core GPU/CPU or the like. The circulation component 4 may be connected in series to an external circulating cooling tower loop, thereby providing a circulating refrigerant to the circulation component 4 for heat dissipation of one end of the heat transfer component 2 inserted in the circulation cavity of the circulation branch 3.

It is worth mentioning that to facilitate disassembly of the detachable mechanism 5 used in the present disclosure, the detachable mechanism 5 can achieve a connection between the circulation component 4 and the cabinet 1, and also can achieve the connection between the circulation branch 3 and the other end of the heat transfer component 2. The circulation branch 3 needs to be hermetically connected to the other end of the heat transfer component 2, to avoid leakage of the refrigerant.

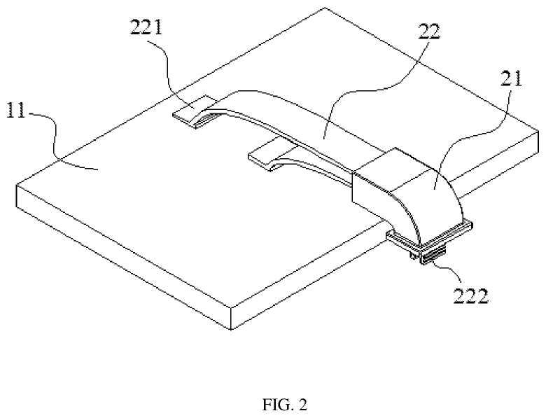

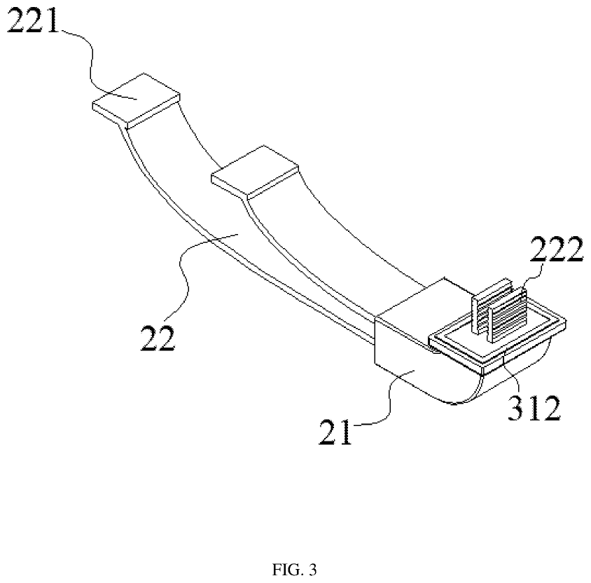

Specifically, as shown in FIG. 2 and FIG. 3, the heat transfer component 2 may comprise a docking cover 21 and a heat-conducting strip 22. The docking cover 21 may be fixed to the cabinet 1, and one end of the docking cover 21 is positioned inside the cabinet 1 and the other end thereof is positioned outside the cabinet 1. The docking cover 21 is mainly configured to insulate the heat-conducting strip 22 to avoid accidental contact and scalding outside, and to fit seal the circulation branch 3. One end of the heat-conducting strip 22 is in contact with the heat generating spot of the heat dissipation element 11, and the other end of the heat-conducting strip 22 passes through the docking cover 21 and extends downward. In this way, when the detachable mechanism 5 drives the circulation component 4 and the circulation branch 3 to move upward and connect to the cabinet 1, the other end of the heat-conducting strip 22 may be inserted into the circulation cavity of the circulation branch 3, and the circulation branch 3 may be pressed and come into contact with the docking cover 21, thereby forming a sealing effect.

In actual use, the docking cover 21 may be made of a heat insulation material, and the docking cover 21 and the heat-conducting strip 22 may be formed by embedded integration of injection molding. Of course, the docking cover 21 and the heat-conducting strip 22 may also be connected by means of a snap-on structure, but the present disclosure is not limited thereto.

Further, a heat-conducting base 221 is provided at one end of the heat-conducting strip 22, and a heat-conducting material is filled between the heat-conducting base 221 and the heat dissipation element 11.

In practical application, the heat-conducting base 221 is tightly crimped with a metal protective shell of the core heat generating spot (CPU or GPU) of the server. The heat-conducting material may be heat-conducting silicone grease or other heat-conducting materials. By filling the heat-conducting material, the heat from the heat generating spot can be transferred to the heat-conducting base 221, and a heat dissipation area of the core heat generating spot can be expanded by means of the heat-conducting base 221.

Further, a plurality of sawtooth grooves 222 are respectively arranged on two sides of the other end of the heat-conducting strip 22, such that a contact area between the other end of the heat-conducting strip 22 and the refrigerant is increased by arranging the plurality of sawtooth grooves 222, thereby improving heat exchange effects.

Further, the heat-conducting strip 22 is made of a flexible material, such that the heat-conducting strip 22 can be bent to come into contact with heat dissipation spots which are not in the same straight line. There are a plurality of heat-conducting strips 22, and the plurality of heat-conducting strips 22 are arranged at intervals from top to bottom.

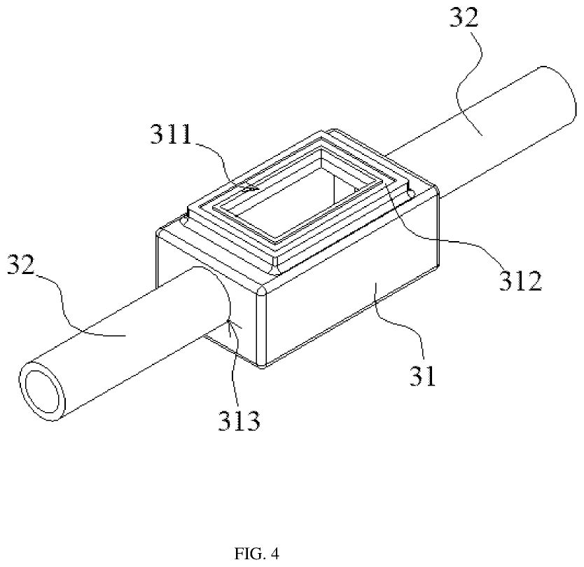

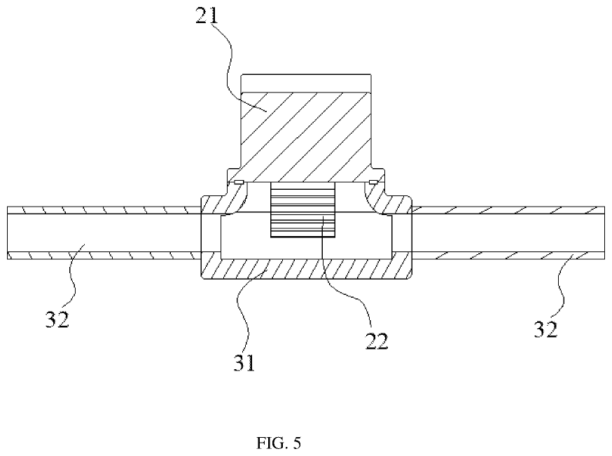

In an implementable embodiment, referring to FIG. 4 and FIG. 5 again, the circulation branch 3 may include a docking seat 31. A top end of the docking seat 31 is provided with a docking opening 311 and a sealing component 312, where the docking opening 311 is arranged corresponding to the other end of the heat-conducting strip 22, such that the other end of the heat-conducting strip 22 can be inserted into the docking seat 31 through the docking opening 311. The sealing component 312 is positioned between the docking seat 31 and the docking cover 21, such that when the docking seat 31 is pressed and comes into contact with the docking cover 21, the sealing component 321 can improve the sealing effect.

Each of two ends of the docking seat 31 is respectively provided with a communication hole 313 communicated with the docking opening 311, and the two communication holes 313 are respectively communicated with the circulation component 4 through a duct 32. The duct 32 may be in threaded connection with the communication holes 313 and/or the circulation component 4.

In practical application, one cabinet 1 may be internally provided with a plurality of heat dissipation elements 11, and correspondingly a plurality of heat transfer components 2 and a plurality of circulation branches 3 need to be provided. That is, there are a plurality of heat dissipation elements 11, a plurality of heat transfer components 2 and a plurality of circulation branches 3, and number of the heat dissipation elements 11 is equal to number of the heat transfer components 2 and number of the circulation branches 3.

In an implementable embodiment, referring to FIG. 6 again, the circulation component 4 may comprise a liquid inlet pipe 41 and a liquid outlet pipe 42. The liquid inlet pipe 41 and the liquid outlet pipe 42 are arranged at intervals, one end of the circulation branch 3 is communicated with the liquid inlet pipe 41, and the other end of the circulation branch 3 is communicated with the liquid outlet pipe 42. The refrigerant entering from the liquid inlet pipe 41 is transferred, through the circulation branch 3 for heat exchange, to the liquid outlet pipe 42, and then enters the external cooling tower for circulation to cool down, and then enters the liquid inlet pipe 41 again, thus forming a heat exchange cycle.

In practical application, the circulation component 4 further includes an upper support plate 43 and a lower support plate 44. Two ends of the upper support plate 43 are respectively connected to a top of the liquid inlet pipe 41 and a top of the liquid outlet pipe 42; and two ends of the lower support plate 44 are respectively connected to a bottom of the liquid inlet pipe 41 and a bottom of the liquid outlet pipe 42. In this way, the liquid inlet pipe 41, the liquid outlet pipe 42 and the circulation branch 3 constitute a whole, which facilitates installation and disassembly.

In an implementable embodiment, the detachable mechanism 5 may include a screw 51 and a tightening nut 52.

A C-shaped plate 12 is arranged on the top of the cabinet 1, and the C-shaped plate 12 is provided with a groove 121. The screw 51 is fixed to the upper support plate 43. When the circulation component 4 is connected to the cabinet 1, the screw 51 is positioned in the groove 121, the nut 52 is positioned above the C-shaped plate 12, and the circulation component 4 is positioned below the C-shaped plate 12. The tightening nut 52 may be in threaded connection with the screw 51, and the tightening nut 52 drives the circulation component 4 to move upward to contact and clamp the C-shaped plate 12.

Further, the detachable mechanism 5 may also include an L-shaped plate 53. The L-shaped plate 53 is connected to the cabinet 1, and a position limit region 531 is formed between the L-shaped plate 53 and the cabinet 1, where one side of the circulation component 4 is positioned within the position limit region 531.

In actual use, when it is necessary to connect the circulation component 4 to the cabinet 1, and when the circulation branch 3 is hermetically connected to the heat transfer component 2, a side of the circulation component 4 may first be moved into the position limit region 531 and brought into contact with the L-shaped plate 53. At this moment, the docking seat 31 is positioned directly below the docking cover 21, such that the docking seat 31 is aligned with the docking cover 21. Next, the screw 51 stretches out of the groove 121 and is in threaded connection with the nut 52. The tightening nut 52 drives the circulation component 4 and the circulation branch 3 to move upward, such that the circulation component 4 is fixed to the cabinet 1, and the docking seat 31 and the docking cover 21 are hermetically connected under pressure.

Based on the same inventive concept, the present disclosure also provides a data center, which includes the cold plate type data center device described above.

As can be seen, according to the technical solutions provided by the present disclosure, by arranging the heat transfer component, the circulation branch, the circulation component and the detachable mechanism, the detachable mechanism connects the circulation component to the cabinet and hermetically connects the circulation branch to the other end of the heat transfer component, such that the heat transfer component transfers heat from the heat dissipation element to a circulating refrigerant in the circulation branch for heat exchange, thus implementing heat dissipation of the heat dissipation element. Meanwhile, the detachable mechanism connects the circulation component to the cabinet, and hermetically connects the circulation branch to the other end of the heat transfer component. Therefore, when it is necessary for maintenance or repair due to poor heat dissipation caused by impurity adhesion to a contact end between the heat transfer component and the refrigerant, it is only required to disassemble the detachable mechanism, which is convenient for disassembly and operation.

Further, a plurality of sawtooth grooves are respectively arranged on two sides of the other end of the heat-conducting strip, such that a contact area between the other end of the heat-conducting strip and the refrigerant is increased by arranging the plurality of sawtooth grooves, thereby improving the heat exchange effects.

The examples set forth above are only illustrated as preferred examples of the present disclosure, and are not intended to limit the present disclosure. All modifications, equivalent substitutions and improvements made within the spirit and principles of the present disclosure shall fall within the protection scope of the present disclosure.

What is claimed is:

1. A cold plate type data center device, at least comprising a cabinet, a heat transfer component, a circulation branch, a circulation component and a detachable mechanism, wherein a heat dissipation element is arranged in the cabinet;
one end of the heat transfer component is in contact with the heat generating spot of the heat dissipation element, and other end of the heat transfer component passes through the cabinet and is positioned in a circulation cavity in the circulation branch;
the circulation branch is communicated with the circulation component, such that a refrigerant in the circulation component flows through the circulation branch; and
the detachable mechanism connects the circulation component to the cabinet, and hermetically connects the circulation branch to the other end of the heat transfer component.

2. The cold plate type data center device according to claim 1, wherein the heat transfer component comprises a docking cover and a heat-conducting strip; and
the docking cover is fixed to the cabinet, one end of the heat-conducting strip is in contact with the heat generating spot of the heat dissipation element, and other end of the heat-conducting strip passes through the docking cover and extends downward.

3. The cold plate type data center device according to claim 2, wherein one end of the heat-conducting strip is provided with a heat-conducting base, and a heat-conducting material is filled between the heat-conducting base and the heat dissipation element;
two sides of the other end of the heat-conducting strip are respectively provided with a plurality of sawtooth grooves; and
the heat-conducting strip is made of a flexible material, a plurality of the heat-conducting strips being provided, and the plurality of heat-conducting strips being arranged at intervals from top to bottom.

4. The cold plate type data center device according to claim 2, wherein the circulation branch comprises a docking seat;
a top end of the docking seat is provided with a docking opening and a sealing component, wherein the docking opening is arranged corresponding to the other end of the heat-conducting strip, and the sealing component is positioned between the docking seat and the docking cover; and
each of two ends of the docking seat is respectively provided with a communication hole communicated with the docking opening, and the two communication holes are respectively communicated with the circulation component through a duct.

5. The cold plate type data center device according to claim 4, wherein there are a plurality of the heat dissipation elements, a plurality of the heat transfer components, and a plurality of the circulation branches; and
number of the heat dissipation elements is equal to number of the heat transfer components and number of the circulation branches.

6. The cold plate type data center device according to claim 5, wherein the circulation component comprises a liquid inlet pipe and a liquid outlet pipe; and
the liquid inlet pipe and the liquid outlet pipe are arranged at intervals, one end of the circulation branch is communicated with the liquid inlet pipe, and other end of the circulation branch is communicated with the liquid outlet pipe.

7. The cold plate type data center device according to claim 6, wherein the circulation component further comprises an upper support plate and a lower support plate;
two ends of the upper support plate are respectively connected to a top of the liquid inlet pipe and a top of the liquid outlet pipe; and
two ends of the lower support plate are respectively connected to a bottom of the liquid inlet pipe and a bottom of the liquid outlet pipe.

8. The cold plate type data center device according to claim 7, wherein the detachable mechanism comprises a screw and a tightening nut;
a C-shaped plate is arranged on the cabinet, and the C-shaped plate is provided with a groove;
the screw is fixed to the upper support plate; and
when the circulation component is connected to the cabinet, the screw is positioned in the groove, and the tightening nut is in threaded connection with the screw.

9. The cold plate type data center device according to claim 8, wherein the detachable mechanism further comprises an L-shaped plate; and
the L-shaped plate is connected to the cabinet, and a position limit region is formed between the L-shaped plate and the cabinet, one side of the circulation component being positioned within the position limit region.

10. A data center comprising a cold plate type data center device, wherein the cold plate type data center device at least comprising a cabinet, a heat transfer component, a circulation branch, a circulation component and a detachable mechanism, wherein a heat dissipation element is arranged in the cabinet;
one end of the heat transfer component is in contact with the heat generating spot of the heat dissipation element, and other end of the heat transfer component passes through the cabinet and is positioned in a circulation cavity in the circulation branch;
the circulation branch is communicated with the circulation component, such that a refrigerant in the circulation component flows through the circulation branch; and
the detachable mechanism connects the circulation component to the cabinet, and hermetically connects the circulation branch to the other end of the heat transfer component.

11. The data center according to claim 10, wherein the heat transfer component comprises a docking cover and a heat-conducting strip; and
the docking cover is fixed to the cabinet, one end of the heat-conducting strip is in contact with the heat generating spot of the heat dissipation element, and other end of the heat-conducting strip passes through the docking cover and extends downward.

12. The data center according to claim 11, wherein one end of the heat-conducting strip is provided with a heat-conducting base, and a heat-conducting material is filled between the heat-conducting base and the heat dissipation element;
two sides of the other end of the heat-conducting strip are respectively provided with a plurality of sawtooth grooves; and
the heat-conducting strip is made of a flexible material, a plurality of the heat-conducting strips being provided, and the plurality of heat-conducting strips being arranged at intervals from top to bottom.

13. The data center according to claim 11, wherein the circulation branch comprises a docking seat;
a top end of the docking seat is provided with a docking opening and a sealing component, wherein the docking opening is arranged corresponding to the other end of the heat-conducting strip, and the sealing component is positioned between the docking seat and the docking cover; and
each of two ends of the docking seat is respectively provided with a communication hole communicated with the docking opening, and the two communication holes are respectively communicated with the circulation component through a duct.

14. The data center according to claim 13, wherein there are a plurality of the heat dissipation elements, a plurality of the heat transfer components, and a plurality of the circulation branches; and
number of the heat dissipation elements is equal to number of the heat transfer components and number of the circulation branches.

15. The data center according to claim 14, wherein the circulation component comprises a liquid inlet pipe and a liquid outlet pipe; and
the liquid inlet pipe and the liquid outlet pipe are arranged at intervals, one end of the circulation branch is communicated with the liquid inlet pipe, and other end of the circulation branch is communicated with the liquid outlet pipe.

16. The data center according to claim 15, wherein the circulation component further comprises an upper support plate and a lower support plate;
two ends of the upper support plate are respectively connected to a top of the liquid inlet pipe and a top of the liquid outlet pipe; and
two ends of the lower support plate are respectively connected to a bottom of the liquid inlet pipe and a bottom of the liquid outlet pipe.

17. The data center according to claim 16, wherein the detachable mechanism comprises a screw and a tightening nut;
a C-shaped plate is arranged on the cabinet, and the C-shaped plate is provided with a groove;
the screw is fixed to the upper support plate; and
when the circulation component is connected to the cabinet, the screw is positioned in the groove, and the tightening nut is in threaded connection with the screw.

18. The data center according to claim 17, wherein the detachable mechanism further comprises an L-shaped plate; and
the L-shaped plate is connected to the cabinet, and a position limit region is formed between the L-shaped plate and the cabinet, one side of the circulation component being positioned within the position limit region.
